(19) United States
(12) Patent Application Publication
(10) Pub. No.: US 2025/0317085 A1
(43) Pub. Date: Oct. 9, 2025

(54) METHOD FOR DIAGNOSING FAILURE IN HOME APPLIANCE, AND HOME APPLIANCE

(71) Applicants: SAMSUNG ELECTRONICS CO., LTD., Suwon-si (KR); Seoul National University R&DB FOUNDATION, Seoul (KR)

(72) Inventors: Jonghyun SHIN, Suwon-si (KR); Jungik HA, Seoul (KR); Jeonghwan KIM, Seoul (KR); Junseok KIM, Suwon-si (KR); Youngjae PARK, Suwon-si (KR); Jaehoon SHIM, Seoul (KR); Jehyung CHO, Suwon-si (KR)

(73) Assignees: SAMSUNG ELECTRONICS CO., LTD., Suwon-si (KR); Seoul National University R&DB FOUNDATION, Seoul (KR)

(21) Appl. No.: 19/244,886

(22) Filed: Jun. 20, 2025

Related U.S. Application Data
(63) Continuation of application No. PCT/KR2023/017127, filed on Oct. 31, 2023.

(30) Foreign Application Priority Data
Dec. 22, 2022 (KR) 10-2022-0182176
Mar. 23, 2023 (KR) 10-2023-0038112

(51) Int. Cl. H02P 29/024; G05B 23/02

(52) U.S. Cl. CPC H02P 29/024; G05B 23/0281

(57) ABSTRACT

A method of diagnosing a fault in a home appliance may include applying, to a plurality of switches included in an inverter, switching control signals that change on and off states of the plurality of switches; obtaining, through a current sensor, current peak value information about the motor based on the switching control signals; and identifying the fault in the home appliance by applying the obtained current peak value information to a fault diagnosis model that is pre-trained to infer the fault in the home appliance.

### CROSS-REFERENCE TO RELATED APPLICATIONS

This application is a continuation application of International Application No. PCT/KR2023/017127, filed on Oct. 31, 2023, which claims priority to Korean Patent Application No. 10-2022-0182176, filed on Dec. 22, 2022, and Korean Patent Application No. 10-2023-0038112, filed on Mar. 23, 2023, the disclosures of which are incorporated by reference herein in their entireties.

### BACKGROUND

### 1. Field

The disclosure relates to a method of diagnosing a fault in a home appliance, and a home appliance.

### 2. Description of Related Art

Home appliances such as refrigerators, air conditioners, washing machines, dryers, vacuum cleaners, dehumidifiers, clothing care devices, shoe care devices, or cooking devices may include a motor and an inverter for driving the motor.

Fault diagnosis of a home appliance ensures seamless operation and safety of the home appliance. For example, when a home appliance is faulty, considerable cost, manpower, and time are required to repair the home appliance unless the faulty part is properly identified. Thus, the need for fault diagnosis to quickly and accurately identify a faulty part of a motor and an inverter has increased.

In general, fault diagnosis of a home appliance uses a diagnostic algorithm in which several diagnostic items are set and each diagnostic item is individually tested. The diagnostic algorithm is applicable only to constant speed and identical load signals that may be converted to a frequency domain, and the diagnostic accuracy may decrease when operating the motor at a variable speed or when an identical load signal is not provided. Alternatively, the diagnostic algorithm requires information about parameters of the motor (e.g., the number of poles or bearing information). Therefore, for motors having different parameters, fault diagnosis is difficult even with respect to the same fault.

To address this issue, fault diagnosis methods using neural network models (NNMs) have recently been developed. The NNM may diagnose the presence of a fault by driving the motor to obtain data, and then using the obtained data as an input value. The fault diagnosis methods using NNMs have high accuracy, but when there is a fatal defect that makes motor operation impossible, the motor may not be driven, and thus, it is impossible to obtain data, making fault diagnosis difficult.

### SUMMARY

According to an aspect of the disclosure, there is provided a method of diagnosing a fault in a home appliance including an inverter configured to convert direct current power into alternating current power to drive a motor, and a current sensor configured to measure current peak value information about the motor, the method including: applying, to a plurality of switches included in the inverter, switching control signals that change on and off states of the plurality of switches; obtaining, through the current sensor, current peak value information about the motor based on the switching control signals; and identifying the fault in the home appliance by applying the obtained current peak value information to a fault diagnosis model that is pre-trained to infer the fault in the home appliance.

The identifying the fault in the home appliance may include identifying a fault type of the home appliance, and wherein the fault type of the home appliance may include at least one of an open fault of at least one of the plurality of switches included in the inverter, an open fault of at least one of a plurality of phases of the inverter, a scale fault of the current sensor, or an offset fault of the current sensor.

The applying the switching control signals to the plurality of switches may include sequentially applying the switching control signals to the plurality of switches according to a predefined order.

The method may further include generating the switching control signals in a pulse-width modulation (PWM) manner according to a plurality of effective voltage vectors.

The generating the switching control signals may include generating the switching control signals based on an application order, magnitudes, or application times of the plurality of effective voltage vectors.

The fault diagnosis model may include a binary classification model having a neural network for identifying a fault type.

The fault diagnosis model may include a plurality of binary classification models that are pre-trained to infer a plurality of fault types, respectively, and wherein the method may further include obtaining diagnosis results for the plurality of fault types through the plurality of binary classification models, respectively.

The fault diagnosis model may include a normality classification model that is pre-trained to infer whether the home appliance is normal, and a plurality of fault type classification models that are pre-trained to infer a plurality of fault types, respectively, and wherein the identifying the fault in the home appliance may include: identifying whether the home appliance is normal by applying the obtained current peak value information to the normality classification model; based on identifying that the home appliance is normal, stopping applying the switching control signals; and based on identifying that the home appliance is abnormal, identifying a fault type of the home appliance by applying the obtained current peak value information to each of the plurality of fault type classification models.

The method may further include: identifying whether there is a short-circuit fault of the inverter; based on identifying that there is the short-circuit fault of the inverter, stopping applying the switching control signals; and based on identifying that there is no short-circuit fault of the inverter, obtaining current peak value information based on the switching control signals.

The method may further include: generating training data regarding a presence of the fault based on the obtained current peak value information; and updating the fault diagnosis model based on the training data.

The method may further include: obtaining a diagnostic command for the home appliance from an external server; and transmitting a fault diagnosis result of the home appliance to the external server through a communication interface of the home appliance.

According to an aspect of the disclosure, there is provided a home appliance including: a motor; an inverter configured to generate alternating current power from direct current power, to drive the motor; a current sensor configured to measure current peak value information about the motor; memory storing instructions, and a fault diagnosis model that is pre-trained to infer a fault in the home appliance; and at least one processor, wherein the instructions, when executed by the at least one processor, cause the home appliance to: apply, to a plurality of switches included in the inverter, switching control signals that change on and off states of the plurality of switches; obtain, through the current sensor, current peak value information about the motor based on the switching control signals; and identify the fault in the home appliance by applying the obtained current peak value information to the fault diagnosis model.

The instructions, when executed by the at least one processor, may cause the home appliance to identify a fault type of the home appliance, and wherein the fault type of the home appliance may include at least one of an open fault of at least one of the plurality of switches included in the inverter, an open fault of at least one of a plurality of phases of the inverter, a scale fault of the current sensor, or an offset fault of the current sensor.

The fault diagnosis model may include a plurality of binary classification models that are pre-trained to infer a plurality of fault types, respectively, and wherein the instructions, when executed by the at least one processor, may cause the home appliance to obtain diagnosis results for the plurality of fault types through the plurality of binary classification models, respectively.

The fault diagnosis model may include a normality classification model that is pre-trained to infer whether the home appliance is normal, and a plurality of fault type classification models that are pre-trained to infer a plurality of fault types, respectively, and wherein the instructions, when executed by the at least one processor, may cause the home appliance to: identify whether the home appliance is normal by applying the obtained current peak value information to the normality classification model; stop, based on identifying that the home appliance is normal, applying the switching control signals; and identify, based on identifying that the home appliance is abnormal, a fault type of the home appliance by applying the obtained current peak value information to each of the plurality of fault type classification models.

### BRIEF DESCRIPTION OF THE DRAWINGS

The above and other aspects and features of embodiments of the present disclosure will become more apparent from the following detailed description taken in conjunction with the accompanying drawings, in which:

FIG. 1 is a diagram illustrating a fault diagnosis operation of a home appliance according to an embodiment of the present disclosure;

FIG. 2 is a diagram illustrating a structure of a home appliance according to an embodiment of the present disclosure;

FIG. 3 is a flowchart of a method of diagnosing a fault in a home appliance, according to an embodiment of the present disclosure;

FIG. 4 is a flowchart of a method of diagnosing a fault in a home appliance, according to an embodiment of the present disclosure;

FIG. 5 is a diagram illustrating a process of obtaining current peak value information in an inverter circuit, according to an embodiment of the present disclosure;

FIG. 6A is a vector diagram illustrating a basic voltage vector during space vector pulse-width modulation control, according to an embodiment of the present disclosure;

FIG. 6B is a diagram illustrating a basic voltage vector and current peak value information detected corresponding thereto during space vector pulse-width modulation control, according to an embodiment of the present disclosure;

FIG. 7 is a graph showing current peak value information detected according to an application order of basic voltage vectors during space vector pulse-width modulation control, according to an embodiment of the present disclosure;

FIGS. 8A and 8B are examples of an inverter circuit according to an embodiment of the present disclosure;

FIG. 9 is a diagram showing fault types, training data, and test data of a fault diagnosis model, according to an embodiment of the present disclosure;

FIG. 10 is a diagram for describing fault types of a home appliance according to an embodiment of the present disclosure;

FIG. 11 is a diagram for describing an operation in which a fault diagnosis model individually diagnoses a plurality of fault types, according to an embodiment of the present disclosure;

FIGS. 12 to 16 are graphs showing current peak value information for each fault type and predicted fault types, according to an embodiment of the present disclosure;

FIG. 17 is a flowchart of a method of diagnosing a fault in a home appliance, according to an embodiment of the present disclosure;

FIG. 18 is a block diagram illustrating a configuration of a home appliance according to an embodiment of the present disclosure;

FIG. 19 is a flowchart of a method, performed by a home appliance and an external server, of diagnosing a fault, according to an embodiment of the present disclosure;

FIG. 20 is a flowchart of a method, performed by a home appliance and an external server, of diagnosing a fault, according to an embodiment of the present disclosure; and

FIG. 21 is a flowchart illustrating a method, performed by an external server and home appliances, of updating a fault diagnosis model, according to an embodiment of the present disclosure.

### DETAILED DESCRIPTION

The present disclosure describes and discloses the principle of embodiments of the present disclosure to clarify the scope of the present disclosure and to allow those of skill in the art to carry out the embodiments. The disclosed embodiments may be implemented in various forms.

Like reference numerals denote like elements throughout the present disclosure. The present disclosure does not describe all elements of embodiments, and general content in the art to which the present disclosure pertains or identical content between the embodiments will be omitted. A “module” or “unit” used herein may be implemented with software, hardware, firmware, or a combination thereof, and depending on embodiments, a plurality of “modules” or “units” may be implemented as one element, or one “module” or “unit” may include a plurality of elements.

In a description of an embodiment, a detailed description of relevant well-known techniques will be omitted when it unnecessarily obscures the gist of the present disclosure. In addition, ordinal numerals (e.g., ‘first’, ‘second’, and the like) used in the description of the disclosure are identifier codes for distinguishing one component from another.

In addition, in the present disclosure, it should be understood that when components are “connected” or “coupled” to each other, the components may be directly connected or coupled to each other, but may alternatively be connected or coupled to each other with a component therebetween, unless specified otherwise.

Hereinafter, various embodiments of the present disclosure and the operating principle thereof will be described with reference to the accompanying drawings.

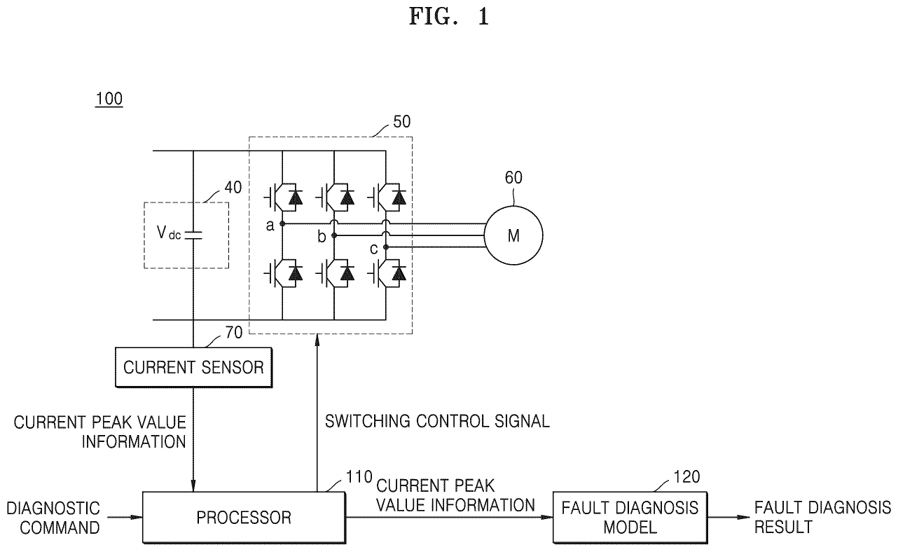

FIG. 1 is a diagram illustrating a fault diagnosis operation of a home appliance according to an embodiment of the present disclosure.

Referring to FIG. 1, a home appliance 100 according to an embodiment of the present disclosure may include an inverter 50, a motor 60, a current sensor 70, a processor 110, and a fault diagnosis model 120. In the home appliance 100 according to an embodiment of the present disclosure, a circuit to which the inverter 50, the motor 60, and the current sensor 70 are connected may be referred to as an ‘inverter circuit’.

The home appliance 100 may be implemented in the form of, for example, a refrigerator, an air conditioner, a washing machine, a dryer, a vacuum cleaner, a dehumidifier, a clothes care device, a shoe care device, or a cooking device. The home appliance 100 is operated by the motor 60 and the inverter 50 that drives the motor 60, and fault diagnosis of the inverter circuit is essential to ensure seamless operation and safety of the home appliance 100.

The inverter 50 may be a power conversion device having a plurality of switching elements. The inverter 50 may convert direct current (DC) power received from a DC link capacitor 40 into alternating current power, and supply the alternating current power to the motor 60.

Fault types of the home appliance 100 may include an open fault of an inverter switch, a phase open fault of the inverter 50, and the like. In addition, the fault types of the home appliance 100 may include a scale fault of the current sensor 70, an offset fault of the current sensor 70, and the like.

The home appliance 100 according to an embodiment of the present disclosure may generate input data to be applied to the fault diagnosis model 120 for fault diagnosis of the home appliance 100, and apply the generated input data to the fault diagnosis model 120, to diagnose a fault in the home appliance 100. The input data for the fault diagnosis model 120 may include current peak value information about the inverter circuit. For example, the current peak value information may include a phase current, a DC link current, a d-axis/q-axis current, and the like of the motor 60. For example, the d-axis/q-axis current may be obtained by converting a three-phase current of the motor 60 detected by the current sensor 70 into a two-phase current of a rotating coordinate system.

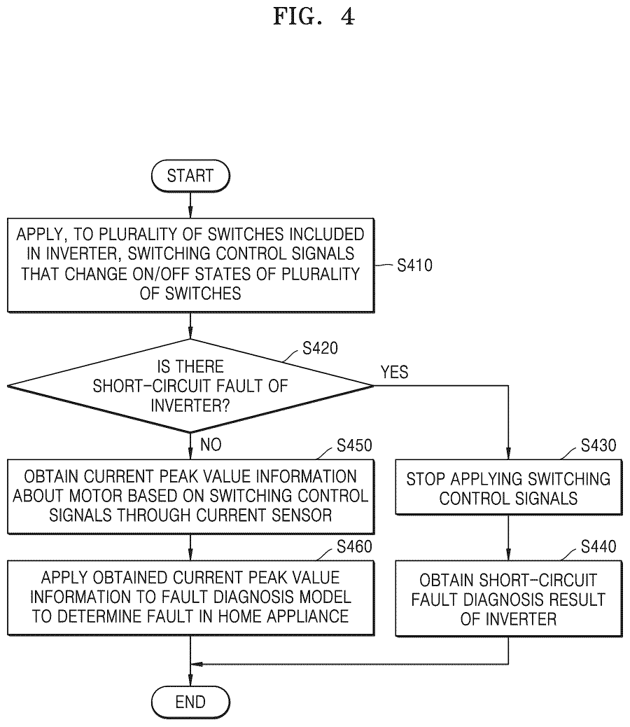

In addition, the fault types of the home appliance 100 may include a short-circuit fault of a switch of the inverter 50. However, a short-circuit fault of an inverter switch causes an abnormal overcurrent, and thus may be diagnosed in a separate manner. In an embodiment, when a short-circuit fault of an inverter switch is diagnosed, the home appliance 100 may terminate the fault diagnosis operation (see FIG. 4).

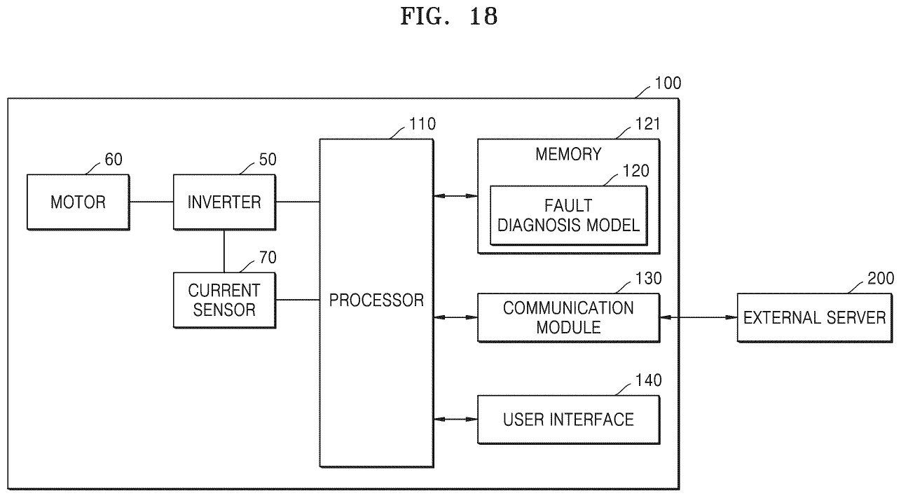

In an embodiment, the processor 110 may receive a diagnostic command. The processor 110 may perform an operation for fault diagnosis of the home appliance 100 according to the diagnostic command. For example, the diagnostic command may be received through a user interface 140 (see FIG. 18) of the home appliance 100. For example, the diagnostic command may be received from an external server 200 (see FIG. 18) through a communication module 130 (see FIG. 18) of the home appliance 100.

In an embodiment, the processor 110 may apply a switching control signal that changes an on/off state of a plurality of switches included in the inverter 50, to the plurality of switches. For example, the inverter 50 may include six switches corresponding to respective phases of a three-phase (a, b, and c) motor. For example, the inverter 50 may open or close the plurality of switches according to the switching control signal of the processor 110, to generate alternating current power and output it to the motor 60.

In an embodiment, the processor 110 may generate a switching control signal by using a particular effective voltage vector, in order to sequentially change the on/off state of the inverter 50 according to a predefined order. For example, the processor 110 may generate a switching control signal by using six effective voltage vectors according to an on/off operation combination of the six switches. For example, the processor 110 may apply, to the inverter 50, the switching control signal generated by using the six effective voltage vectors. For example, the predefined order may be determined based on the order of applying the plurality of effective voltage vectors. In an embodiment, the processor 110 may generate a switching control signal according to a pulse-width modulation (PWM) method.

In an embodiment, the inverter 50 may receive a switching control signal from the processor 110, and perform an on/off operation of the plurality of switches according to an effective voltage vector. The inverter 50 may provide an alternating current to the motor 60 for rotating a rotor of the motor 60. The motor 60 may output a phase current through the alternating current received from the inverter 50.

In an embodiment, when a switching control signal is applied to the inverter 50 by using an effective voltage vector, a phase current flowing through the motor 60 may be the same as any one of the three-phase alternating currents applied to the motor 60. For example, the phase current of the motor 60 may be detected as current peak value information having a peak shape.

In an embodiment, the current sensor 70 may sense the current peak value information about the motor 60 and transmit it to the processor 110. The current sensor 70 may include an analog-to-digital (A/D) converter that digitizes the current peak value information. The processor 110 may obtain the current peak value information through the current sensor 70.

In an embodiment, the processor 110 may input the current peak value information to the fault diagnosis model 120. The processor 110 may control the fault diagnosis model 120 to output a fault diagnosis result of the home appliance 100. The fault diagnosis model 120 may receive the current peak value information as input and infer the presence of a fault according to the fault types of the home appliance 100. In an embodiment, the fault diagnosis model 120 may be a pre-trained artificial intelligence model to infer a fault in the home appliance 100. In an embodiment, the fault diagnosis model 120 may include a binary classification model including a neural network for determining (e.g., identifying) a fault type of the home appliance 100. For example, the fault diagnosis model 120 may include a plurality of binary classification models that are pre-trained to infer a plurality of fault types, respectively. For example, the processor 110 may obtain diagnosis results for the plurality of fault types through the plurality of binary classification models, respectively.

In an embodiment of the present disclosure, the processor 110 and the fault diagnosis model 120 may be implemented together on a microcontroller. For example, the fault diagnosis model 120 may be trained in an external server for artificial intelligence training, and then deployed to an embedded system. It may be executed in the embedded system, and the processor 110 may control a neural network model stored in a memory. For example, the processor 110 may include at least one of a central processing unit (CPU), a graphics processing unit (GPU), an accelerated processing unit (APU), a many-integrated core (MIC) processor, a digital signal processor (DSP), and a neural processing unit (NPU).

The home appliance 100 according to an embodiment of the present disclosure may deploy the fault diagnosis model 120 to an embedded system, and may diagnose a fault in the home appliance 100 in real time under control of the processor 110 on the microcontroller. Thus, the home appliance 100 may quickly determine the presence of a fault in the home appliance 100 and the fault type.

The home appliance 100 according to an embodiment of the present disclosure may obtain input data for the fault diagnosis model 120 even without driving the motor 60. The current peak value information about the motor 60 required as input data for the fault diagnosis model 120 may be obtained through six effective voltage vectors. Thus, because input data for the fault diagnosis model 120 may be obtained even before driving the motor 60, a fatal defect that may occur during an operation of the motor 60 may be prevented, and a fault in the home appliance 100 may be diagnosed for a fault type in which the operation of the motor 60 is impossible. In addition, the process of obtaining data during an operation of the motor 60 is omitted, and thus, current data required for fault diagnosis may be obtained relatively quickly. In addition, a fault in the home appliance 100 may be diagnosed by using the current peak value information according to the six effective voltage vectors, and thus, the number of types of data and the number of pieces of data required for fault diagnosis of the home appliance 100 may be relatively small.

In the home appliance 100 according to an embodiment of the present disclosure, the fault diagnosis model 120 may include a binary classification model, and the binary classification model may include individual neural networks corresponding to a plurality of fault types. Thus, the home appliance 100 may individually diagnose a plurality of fault types of the inverter 50, and thus may accurately determine a complex fault situation in which several types of faults occur in combination.

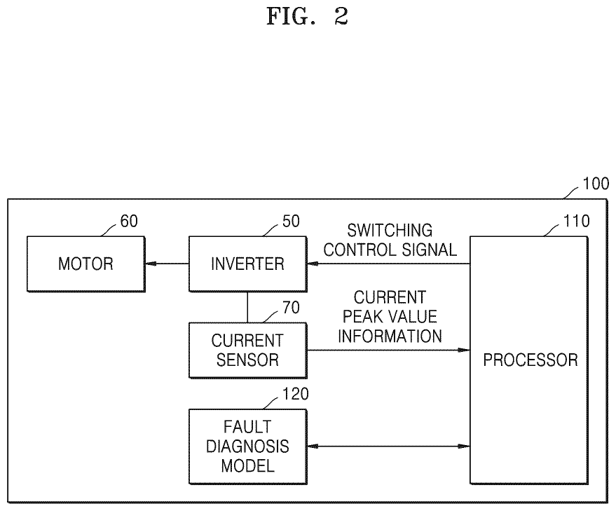

FIG. 2 is a diagram illustrating a structure of a home appliance according to an embodiment of the present disclosure.

The home appliance 100 according to an embodiment of the present disclosure may include the inverter 50, the motor 60, the current sensor 70, the processor 110, and the fault diagnosis model 120.

The inverter 50 is a power conversion device having a plurality of switching elements, and may convert direct current power into alternating current power. The inverter 50 may convert a direct current voltage stored in a direct current link into a pulse-shaped alternating current voltage having an arbitrary variable frequency by a PWM method so as to drive the motor 60. The plurality of switching elements included in the inverter 50 may include an insulated-gate bipolar transistor (IGBT) and the like.

For example, the inverter 50 may include a switch element pair corresponding to each phase of the three-phase (a, b, and c) motor. For example, the inverter 50 may open or close the switching elements according to a switching control signal of the processor 110 to generate three-phase (a, b, and c) alternating current power and output it to the motor 60.

The motor 60 outputs a driving force to a certain home appliance function module of the home appliance 100. The motor 60 may receive the alternating current power from the inverter 50 and generate a constant torque. The motor 60 may be an arbitrary motor including a stator around which a coil is wound, and a rotor rotating by a magnetic field generated in the coil. For example, the motor 60 may include a brushless direct current (BLDC) motor, which is a kind of permanent magnet synchronous motor (PMSM), or a PMSM.

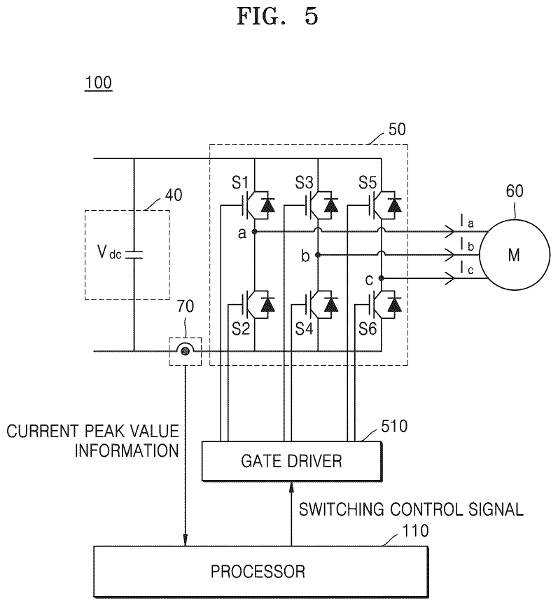

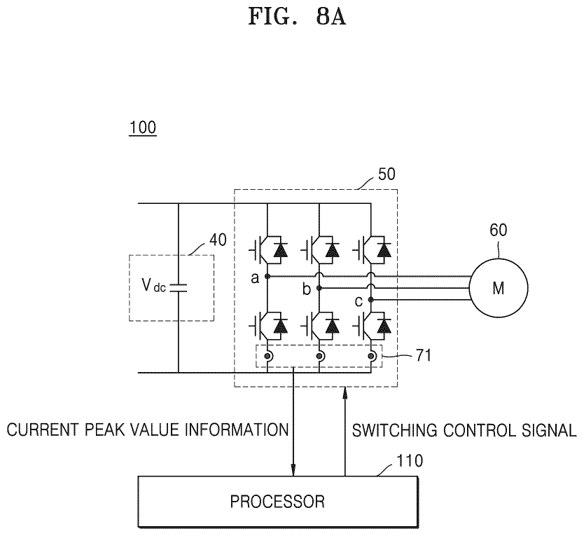

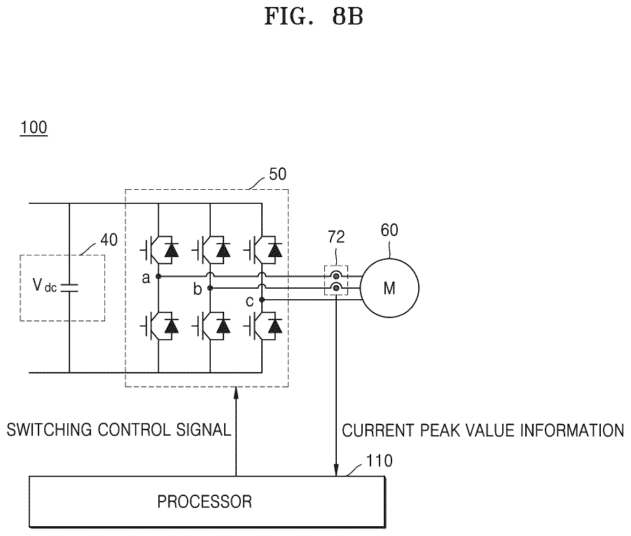

The current sensor 70 may include a shunt resistor, a shunt resistor and an amplifier circuit (operational amplifier (OP-AMP)), a current sensor, a magnetic field sensor (non-contact type), and the like. For example, the current sensor 70 may include a shunt resistor formed between the DC link capacitor and the inverter 50. For example, the current sensor 70 may be formed in a 1-shunt manner in which one shunt resistor is added between the DC link capacitor and the inverter 50 (see FIG. 5). Alternatively, for example, the current sensor 70 may be formed in a 2-shunt or 3-shunt manner in which two or three shunt resistors are added between the DC link capacitor and the inverter 50 (see FIG. 8A). Alternatively, for example, the current sensor 70 may be formed at an output terminal of the inverter 50. For example, the current sensor 70 may include a Hall integrated circuit (IC) formed between the inverter 50 and the motor 60 (see FIG. 8B).

For example, the current sensor 70 may sense a phase current of the motor 60. The current sensor 70 may sense the phase current of the motor 60, digitize the sensed phase current, and transmit the digitized phase current to the processor 110. Alternatively, the current sensor 70 may also sense an output current of the inverter 50. Alternatively, the current sensor 70 may also sense a DC link current.

The processor 110 may include a processor configured to control the overall operation of the home appliance 100. The processor 110 may be implemented as at least one processor. The at least one processor may include at least one of a CPU, a GPU, an APU, an MIC processor, a DSP, and an NPU.

The processor 110 may include a separate processor configured to control an on/off state of the plurality of switching elements of the inverter 50. For example, the processor 110 may be embedded in a printed circuit board configured to control the inverter 50. In an embodiment, the processor 110 may include a main processor configured to control the overall operation of the home appliance 100, and a first processor configured to control the operation of the inverter 50, but is not limited thereto.

In an embodiment of the present disclosure, the processor 110 may be included in a MICOM (micro-computer, microprocessor computer, microprocessor controller), a microprocessor unit (MPU), a microcontroller unit (MCU), or the like in which an artificial neural network (ANN) is embedded. For example, the processor 110 may be included in a microcontroller in which the fault diagnosis model 120 is embedded, and may perform an operation for controlling the fault diagnosis model 120. For example, a one-hot encoding method may be used for embedding the artificial neural network.

The fault diagnosis model 120 may be an artificial neural network model that is pre-trained to infer a fault in the home appliance 100 through a neural network operation. The fault diagnosis model 120 may receive current peak value information as input and output the presence of a fault according to the fault types of the home appliance 100.

The artificial neural network may include, for example, a deep neural network (DNN) and may include, for example, a convolutional neural network (CNN), a deep neural network (DNN), a recurrent neural network (RNN), a restricted Boltzmann machine (RBM), a deep belief network (DBN), a bidirectional recurrent deep neural network (BRDNN), a deep Q-network, or the like, but is not limited thereto.

In an embodiment, the fault diagnosis model 120 may be trained through data obtained in a normal state and data obtained in fault states according to a plurality of fault types. For example, the fault diagnosis model 120 may be a supervised learning-based neural network model. For example, the fault diagnosis model 120 may be trained in an external server for artificial intelligence training, and then deployed according to an embedded system.

The fault diagnosis model 120 may include a binary classification model having a neural network for determining a fault type. The binary classification model is a model that classifies input data into one of two groups. A rectified linear unit (ReLU) function or a sigmoid function, which is one of activation functions, may be applied for binary classification. However, the binary classification model is not limited to the above-described example.

In an embodiment of the present disclosure, the fault diagnosis model 120 may include a plurality of binary classification models having individual neural networks respectively for a plurality of fault types. For example, the fault diagnosis model 120 may be pre-trained to infer each of a plurality of fault types. For example, the fault diagnosis model 120 may include a normality classification model that is pre-trained to infer whether the home appliance 100 is normal, and a plurality of fault type classification models that are pre-trained to respectively infer a plurality of fault types of the home appliance 100. For example, the plurality of fault type classification models may include an open fault classification model for a switch of the inverter 50, a phase open fault classification model for the inverter 50, a scale fault classification model for the current sensor 70, an offset fault classification model for the current sensor 70, and the like.

The processor 110 according to an embodiment of the present disclosure may apply a switching control signal that changes an on/off state of the plurality of switches included in the inverter 50, to the plurality of switches. The processor 110 may obtain current peak value information about the motor 60 based on the switching control signal through the current sensor 70. The processor 110 may apply the obtained current peak value information to the fault diagnosis model 120 to determine a fault in the home appliance 100.

The processor 110 according to an embodiment of the present disclosure may determine a fault type of the home appliance 100. The fault types of the home appliance 100 may include at least one of an open fault of at least one of a plurality of switches included in the inverter 50, an open fault of at least one of a plurality of phases of the inverter 50, a scale fault of the current sensor 70, or an offset fault of the current sensor 70.

The processor 110 according to an embodiment of the present disclosure may sequentially apply switching control signals to the plurality of switches according to a predefined order.

The processor 110 according to an embodiment of the present disclosure may generate PWM-type switching control signals according to a plurality of effective voltage vectors.

The processor 110 according to an embodiment of the present disclosure may generate the switching control signals based on an application order, magnitudes, or application times of the plurality of effective voltage vectors.

The processor 110 according to an embodiment of the present disclosure may obtain a diagnosis result for each of the plurality of fault types through the plurality of binary classification models.

The processor 110 according to an embodiment of the present disclosure may apply the obtained current peak value information to the normality classification model to determine whether the home appliance 100 is normal. For example, the processor 110 may stop applying the switching control signals when the home appliance 100 is identified as normal. For example, when the home appliance 100 is identified as abnormal, the processor 110 may apply the obtained current peak value information to each of the plurality of fault type classification models to determine the fault type of the home appliance 100.

The processor 110 according to an embodiment of the present disclosure may determine whether there is a short-circuit fault of the inverter 50. Based on determining that there is a short-circuit fault of the inverter 50, the processor 110 may stop applying the switching control signals. Based on determining that there is no short-circuit fault of the inverter 50, the processor 110 may obtain current peak value information based on the switching control signals.

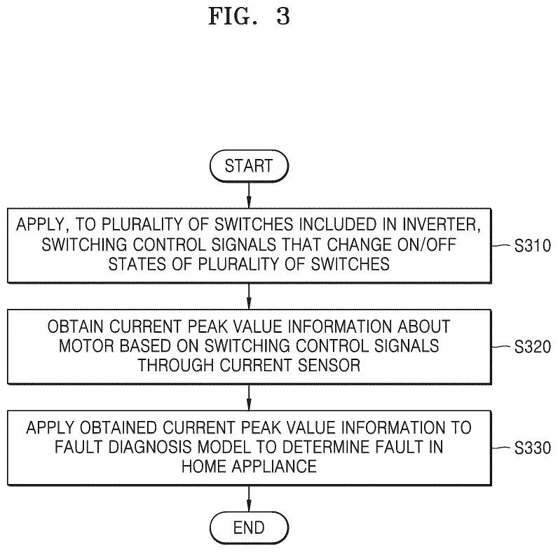

FIG. 3 is a flowchart of a method of diagnosing a fault in a home appliance, according to an embodiment of the present disclosure.

Referring to FIG. 3, a method of diagnosing a fault in the home appliance 100 according to an embodiment of the present disclosure is according to an embodiment, and each operation constituting the method is not limited to the embodiment illustrated in FIG. 3, and some operations may be added, modified, or omitted as necessary.

In the present disclosure, an embodiment in which the home appliance 100 according to an embodiment operates according to the method of diagnosing a fault in the home appliance 100 will be mainly described.

In operation S310, the home appliance 100 may apply, to the plurality of switches included in the inverter 50, switching control signals that change on/off states of the plurality of switches.

For example, the home appliance 100 may sequentially apply the switching control signals to the plurality of switches of the inverter 50 according to a predefined order. For example, the home appliance 100 may generate PWM-type switching control signals according to a plurality of effective voltage vectors. For example, the home appliance 100 may generate the switching control signals based on an application order, magnitudes, or application times of the plurality of effective voltage vectors. For example, the plurality of effective voltage vectors may include six effective voltage vectors for changing on/off states of three pairs of switch elements corresponding to the respective phases of the three-phase (a, b, and c) motor of the inverter 50. For example, each of the plurality of effective voltage vectors may have a phase difference of 60 degrees.

In operation S320, the home appliance 100 may obtain current peak value information about the motor 60 based on the switching control signals through the current sensor 70. For example, the inverter 50 that has received the switching control signals may convert direct current power into an alternating current and apply the alternating current to the motor 60. The motor 60 that has received the alternating current may generate a phase current. The current sensor 70 may sense the phase current of the motor 60 and transmit the sensed phase current to the processor 110. For example, the processor 110 may use the obtained phase current as input data for the fault diagnosis model 120. In an embodiment, the motor 60 may not be driven by the alternating current of the inverter 50 generated according to the six effective voltage vectors. For example, the phase current of the motor 60 may have a current peak shape, rather than a sine wave shape. For example, the home appliance 100 may obtain current peak value information about the phase current of the motor 60 through the current sensor 70.

In operation S330, the home appliance 100 may apply the obtained current peak value information to the fault diagnosis model 120 to determine a fault in the home appliance 100. For example, the fault diagnosis model 120 may be a learning model that is pre-trained to infer a fault in the home appliance 100. For example, the home appliance 100 may input the obtained current peak value information to the fault diagnosis model 120. For example, the current peak value information may be used as input data for the fault diagnosis model 120.

For example, the home appliance 100 may determine a fault type of the home appliance 100. The fault types of the home appliance 100 may include at least one of an open fault of at least one of a plurality of switches included in the inverter 50, an open fault of at least one of a plurality of phases of the inverter 50, a scale fault of the current sensor 70, or an offset fault of the current sensor 70.

For example, the fault diagnosis model 120 may include a binary classification model having a neural network for inferring a fault type.

For example, the fault diagnosis model 120 may include a plurality of binary classification models that are pre-trained to infer a plurality of fault types, respectively. The plurality of binary classification models may include individual neural networks respectively for the plurality of fault types. For example, the home appliance 100 may obtain diagnosis results for the plurality of fault types through the plurality of binary classification models, respectively. For example, the fault diagnosis model 120 may include a normality classification model that is pre-trained to infer whether the home appliance 100 is normal, and a plurality of fault type classification models that are pre-trained to respectively infer a plurality of fault types.

For example, the home appliance 100 may generate training data about the presence of a fault, based on the obtained current peak value information. For example, the home appliance 100 may update the fault diagnosis model 120 based on the training data.

For example, the home appliance 100 may receive a diagnostic command for the home appliance 100 from an external server. For example, the home appliance 100 may transmit a fault diagnosis result of the home appliance 100 to the external server through a communication module (e.g., communication interface).

FIG. 4 is a flowchart of a method of diagnosing a fault in a home appliance, according to an embodiment of the present disclosure.

The method of diagnosing a fault illustrated in FIG. 4 is according to an embodiment, and each operation constituting the method is not limited to the embodiment illustrated in FIG. 4, and some operations may be added, modified, or omitted as necessary.

Referring to FIG. 4, in operation S410, the home appliance 100 may apply, to the plurality of switches included in the inverter 50, switching control signals that change on/off states of the plurality of switches. Operation S410 may correspond to operation S310 of FIG. 3.

In operation S420, the home appliance 100 may determine whether there is a short-circuit fault of the inverter 50. For example, a short-fault of a switch of the inverter 50 may be a hardware fault of the inverter 50. When a switch of the inverter 50 is short-circuited, the inverter 50 causes an overcurrent, and thus, it may be diagnosed in a separate manner. For example, the home appliance 100 may detect an overcurrent of the inverter 50 by using separate hardware. Alternatively, for example, a short-circuit fault of a switch of the inverter 50 may be diagnosed as a short-circuit fault when at least one of the three-phase currents of the inverter 50 is greater than a threshold current defined as an overcurrent.

In operation S430, based on determining that there is a short-circuit fault of the inverter 50, the home appliance 100 may stop applying the switching control signals.

In operation S440, the home appliance 100 may obtain a short-circuit fault diagnosis result of the inverter 50 and stop the fault diagnosis operation of the home appliance 100.

In operation S450, based on determining that there is no short-circuit fault of the inverter 50, the home appliance 100 may obtain current peak value information based on the switching control signals. For example, the home appliance 100 may obtain current peak value information about the motor 60 based on the switching control signals through the current sensor 70.

For example, when an overcurrent of the inverter 50 is not detected, the home appliance 100 may control the inverter 50 until an application time of a preset effective voltage vector elapses. For example, under control of the inverter 50, the motor 60 may generate a phase current, and the current sensor 70 may obtain the phase current of the motor 60. For example, the home appliance 100 may obtain current peak value information about the motor 60 through the current sensor 70.

In operation S460, the home appliance 100 may apply the obtained current peak value information to the fault diagnosis model to determine a fault in the home appliance 100. Operation S460 may correspond to operation S330 of FIG. 3.

Hereinafter, a process of obtaining current peak value information, which is input data for the fault diagnosis model 120, in the home appliance 100 according to an embodiment will be described with reference to FIGS. 5 to 8.

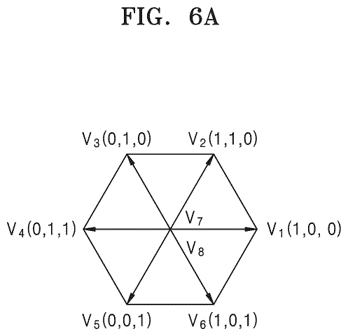

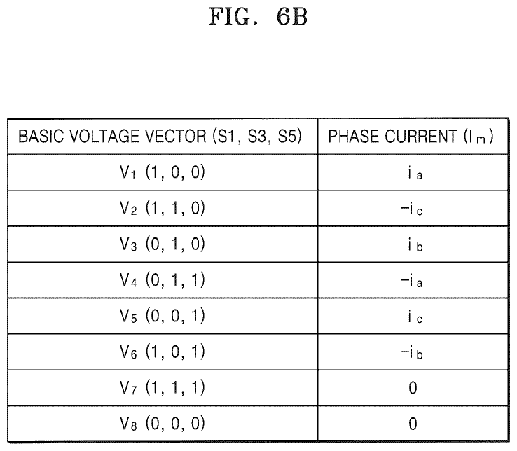

FIG. 5 is a diagram illustrating a process of obtaining current peak value information in an inverter circuit, according to an embodiment of the present disclosure. FIG. 6A is a vector diagram illustrating a basic voltage vector during space vector pulse-width modulation control, according to an embodiment of the present disclosure. FIG. 6B is a diagram illustrating a basic voltage vector and current peak value information detected corresponding thereto during space vector pulse-width modulation control, according to an embodiment of the present disclosure.

Referring to FIG. 5, the inverter 50 may include a switching circuit in which six switches S1, S2, S3, S4, S5, and S6 and diodes are connected in a three-phase full bridge. The six switches S1, S2, S3, S4, S5, and S6 may form switch pairs corresponding to the respective phases of the three-phase (a, b, and c) motor. When the inverter 50 receives signals to turn on or off the switches from a gate driver 510, the inverter 50 may turn on or off the six switches S1, S2, S3, S4, S5, and S6 to generate a three-phase alternating current. The inverter 50 may supply the three-phase alternating current to the motor 60. Three-phase alternating current refers to an alternating current flowing in three electromotive forces having the same frequency and different phases. A direct current voltage is smoothed by the DC link capacitor 40.

The current sensor 70 may include a shunt resistor between one terminal of the DC link capacitor 40 of the inverter 50 and the lower switches S2, S4, and S6. The current sensor 70 may sense a phase current of the motor 60.

The gate driver 510 may receive a switching control signal from the processor 110 and transmit a signal to turn on or off a switch to the inverter 50.

In an embodiment of the present disclosure, the home appliance 100 may detect current peak value information, which is input data for the fault diagnosis model 120, by generating a switching control signal by using space vector pulse-width modulation (SVPWM). The home appliance 100 may use a particular space voltage vector to detect the current peak value information.

In general, when all switches in one leg of the inverter 50 are turned on, a short occurs and an overcurrent flows, and thus, the inverter 50 is controlled in a complementary manner in which, when one of two switches provided in each leg is in an on state, the other is in an off state. Thus, when indicating the on/off states of all switches of the inverter 50, the states of the upper switches S1, S3, and S5 are generally indicated as 1 or 0. Here, 1 means that the switch is closed and energized, and 0 means that the switch is open.

Accordingly, the inverter 50 has eight states according to the combination of the on/off operations of the respective switches S1 to S6, and the SVPWM method is a method of generating switching control signals by using eight basic voltage vectors respectively corresponding to the eight states.

Referring to FIG. 6A, the basic voltage vector may include six effective voltage vectors V1, V2, V3, V4, V5, and V6 and two zero-voltage vectors V7 and V8. The six effective voltage vectors V1, V2, V3, V4, V5, and V6 are arranged to have a phase difference of 60 degrees from each other, and the zero-voltage vectors V7 and V8 are located at their origin. Here, the numbers in the parentheses indicate the on/off states of the switches S1, S3, and S5. The switching control signals generated through the eight basic voltage vectors may control the plurality of switches S1, S2, S3, S4, S5, and S6 in eight on/off states.

Referring to FIG. 6B, when the switching control signals are applied to the inverter 50 by using the effective voltage vectors V1, V2, V3, V4, V5, and V6, the phase current flowing through the motor 60 may be the same as any one of the three-phase alternating currents applied to the motor 60. For example, when the switching control signals are applied to the inverter 50 by using the effective voltage vector of V1(1,0,0), the motor 60 may output an A-phase positive current +ia. For example, when the switching control signals are applied to the inverter 50 by using the effective voltage vector of V2(1,1,0), the motor 60 may output a C-phase negative current −ic. For example, when the switching control signals are applied to the inverter 50 by using the effective voltage vector of V3(0,1,0), the motor 60 may output a B-phase positive current +ib. For example, when the switching control signals are applied to the inverter 50 by using the effective voltage vector of V4(0,1,1), the motor 60 may output an A-phase negative current −ia. For example, when the switching control signals are applied to the inverter 50 by using the effective voltage vector of V5(0,0,1), the motor 60 may output a C-phase positive current +ic. For example, when the switching control signals are applied to the inverter 50 by using the effective voltage vector of V6(1,0,1), the motor 60 may output a B-phase negative current −ib.

In addition, the zero-voltage vectors V7 and V8 are (111) and (000), which indicate states in which all of the upper switches are turned off or all of the lower switches are turned off, and thus, no current flows through the motor 60.

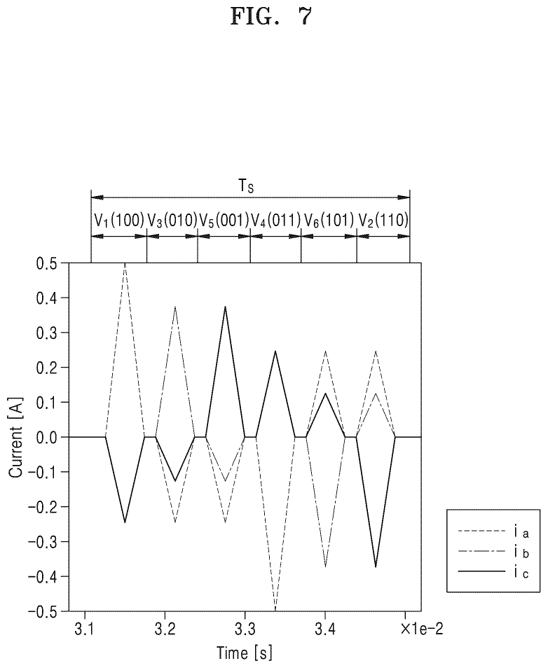

FIG. 7 is a graph showing current peak value information detected according to an application order of basic voltage vectors during space vector pulse-width modulation control, according to an embodiment of the present disclosure.

In an embodiment of the present disclosure, the processor 110 may obtain the phase current of the motor 60, which is input data for the fault diagnosis model 120, by using a particular voltage vector. The processor 110 may control the on/off states of the plurality of switches S1, S2, S3, S4, S5, and S6 based on an application order, magnitudes, and application times of six particular effective voltage vectors. For example, the processor 110 may sequentially control the on/off states of the plurality of switches S1, S2, S3, S4, S5, and S6 according to a preset order. For example, as the magnitude of an effective voltage vector applied to the motor 60, ⅔ Vdc, which is the maximum modulation magnitude in the SVPWM method. For example, as shown in FIG. 7, the application order of the effective voltage vectors applied to the motor 60 may be V1(1,0,0), V3(0,1,0), V5(0,0,1), V4(0,1,1), V6(1,0,1), and V2(1,1,0). For example, the effective voltage vectors may be applied during a sampling period Ts. For example, the application order, magnitudes, and application times of the effective voltage vectors may vary depending on parameter information about the motor.

Referring to FIG. 7, the processor 110 may obtain the phase current of the motor 60 according to a preset application order of the effective voltage vectors. For example, the processor 110 may obtain current peak value information about the motor 60. For example, according to the application order of the effective voltage vectors, the processor 110 may obtain current peak value information in the order of +ia, +ib, +ic, −ia, −ib, and −ic. Thereafter, the processor 110 may stop the inverter 50 to make a zero current.

In addition, because the current sensor 70 according to an embodiment is located between the DC link capacitor 40 and the lower switches S2, S4, and S6 of the inverter 50, the current peak value information may include current information about other phases. For example, when applying V1(1,0,0), the processor 110 may obtain current peak value information of +ia, along with current peak value information of −ib and −ic, which are half the magnitude of +ia. For example, when applying V3(0,1,0), the processor 110 may obtain current peak value information of +ib, along with current peak value information of −ia and −ic, which are half of the magnitude of +ib.

In addition, as described above with reference to FIG. 4, when a short-circuit fault of the inverter 50 is detected, the processor 110 may stop the inverter 50, obtain a short-circuit fault result, and then terminate the fault diagnosis process. For example, based on detecting an overcurrent, the processor 110 may determine a short-circuit fault of the inverter 50. When the processor 110 does not detect an overcurrent, the processor 110 may obtain current peak value information until a preset application time of the effective voltage vector elapses.

In an embodiment of the present disclosure, because the processor 110 detects the phase current of the motor 60 by using a particular effective voltage vector before an operation of the motor 60, the phase current of the motor 60 may be different from the operating current of the motor 60. For example, the phase current of the motor 60 detected through a plurality of effective voltage vectors is detected in a peak shape, and is not detected in a sine wave shape.

FIGS. 8A and 8B are examples of an inverter circuit according to an embodiment of the present disclosure.

In FIGS. 8A and 8B, the home appliance 100 according to an embodiment may include a current sensor 71 or a current sensor 72 instead of the 1-shunt-type current sensor 70 between the DC link capacitor 40 and the lower switches of the inverter 50.

For example, the current sensor 71 may include two or three shunt resistors between the DC link capacitor 40 and the lower switches of the inverter 50, so to be formed in a 2-shunt manner or a 3-shunt manner. For example, two or three shunt resistors may be formed in the leg of the lower switches of the inverter 50. FIG. 8A illustrates the 3-shunt-type current sensor 71.

For example, the current sensor 72 may include two or three Hall ICs installed between the inverter 50 and the motor 60. FIG. 8B illustrates the current sensor 72 including two Hall ICs installed in phase A and phase B. The current sensor 72 may be connected to an output terminal of the inverter 50.

The current sensor 71 and the current sensor 72 may each detect a phase current of the motor 60. The current sensor 71 may also detect a DC link current. The current sensor 72 may also detect an output current of the inverter 50. The current sensor 71 and the current sensor 72 may each transmit current peak value information, which is the phase current of the motor 60, to the processor 110.

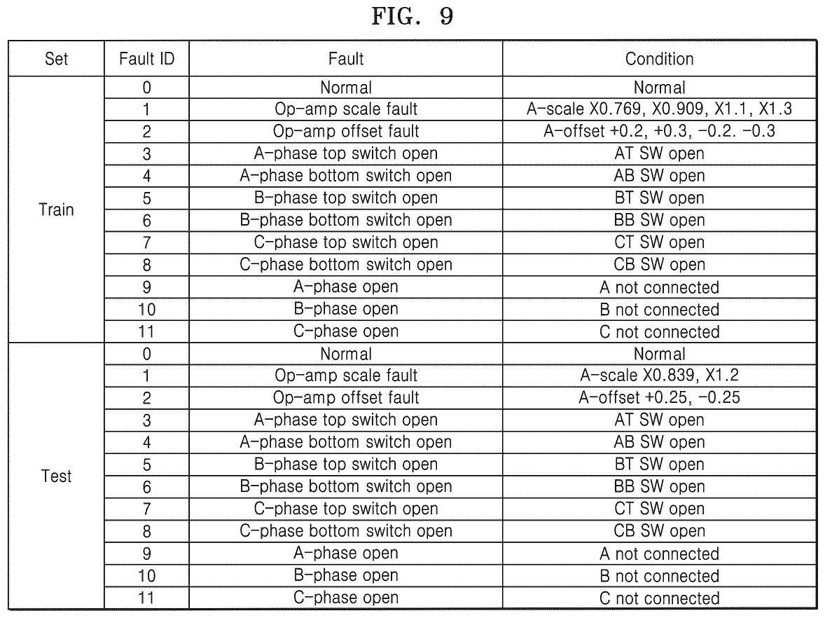

Hereinafter, a process of diagnosing a fault in the home appliance 100 by applying input data to the fault diagnosis model 120 in the home appliance 100 according to an embodiment will be described with reference to FIGS. 9 to 11.

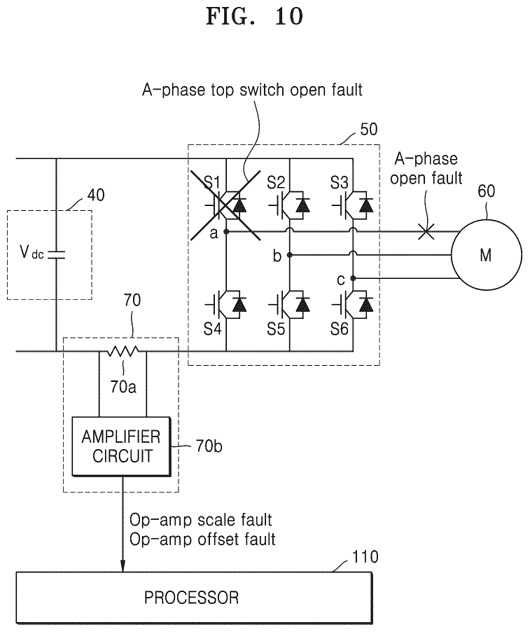

FIG. 9 is a diagram showing fault types, training data, and test data of a fault diagnosis model, according to an embodiment of the present disclosure. FIG. 10 is a diagram for describing fault types of a home appliance according to an embodiment of the present disclosure.

Referring to FIG. 9, the fault diagnosis model 120 may store training data using supervised learning. For example, the fault diagnosis model 120 may be trained through data obtained in a normal state and data obtained in fault states according to a plurality of fault types.

For example, the fault types of the home appliance 100 may include at least one of an open fault of at least one of the plurality of switches S1, S2, S3, S4, S5, and S6 included in the inverter 50, an open fault of at least one of the plurality of phases (a, b, and c) of the inverter 50, a scale fault of the current sensor 70, or an offset fault of the current sensor 70.

For example, the fault types of the home appliance 100 including the three-phase inverter 50 may include an open fault of the A-phase upper switch S1, an open fault of the A-phase lower switch S2, an open fault of the B-phase upper switch S3, an open fault of the B-phase lower switch S4, an open fault of the C-phase upper switch S5, and an open fault of the C-phase lower switch S6. FIG. 10 illustrates an open fault of the A-phase upper switch S1.

For example, the fault types of the home appliance 100 including the three-phase inverter 50 may include an A-phase open fault, a B-phase open fault, and a C-phase open fault. FIG. 10 illustrates an A-phase open fault.

For example, the fault types of the home appliance 100 may include a scale fault of the current sensor 70 and an offset fault of the current sensor 70. Referring to FIG. 10, the current sensor 70 may include a shunt resistor 70a and an amplifier circuit (OP-AMP) 70b. The scale fault of the current sensor 70 may refer to a situation in which the gain of the amplifier circuit 70b is erroneous, and the offset fault of the current sensor 70 may refer to a situation in which the offset of the amplifier circuit 70b is erroneous.

Referring back to FIG. 9, the fault diagnosis model 120 may include a plurality of binary classification models having individual neural networks respectively for a plurality of fault types. For example, the fault diagnosis model 120 may include a feed-forward neural network (FFNN).

For example, the fault diagnosis model 120 may include a normality classification model for the home appliance 100 and a plurality of fault type classification models. The plurality of fault type classification models may include six switch open fault classification models, three phase open fault classification models, a scale fault classification model for the current sensor 70, and an offset fault classification model for the current sensor 70, and the like. For example, the switch open fault classification models may include an open fault classification model for the A-phase upper switch S1, an open fault classification model for the A-phase lower switch S2, an open fault classification model for the B-phase upper switch S3, an open fault classification model for the B-phase lower switch S4, an open fault classification model for the C-phase upper switch S5, and an open fault classification model for the C-phase lower switch S6. For example, the phase open fault classification models may include an A-phase open fault classification model, a B-phase open fault classification model, and a C-phase open fault classification model. For example, the fault diagnosis model 120 may include a plurality of binary classification models capable of diagnosing faults from fault identifier (ID) 0 to fault ID 11.

For example, the normality classification model may be trained through data obtained in a normal state and data obtained in fault states. For example, the open fault classification model for the A-phase upper switch may be trained through data obtained in open fault states of the A-phase upper switch, and data obtained in the other states. For example, the A-phase open fault classification model may be trained through data obtained in A-phase open fault states, and data obtained in the other states.

For example, the scale fault classification model for the current sensor 70 may be trained through data obtained while changing the gain of the current sensor 70 to 0.769, 0.839, 0.909, 1.1, 1.2, and 1.3. For example, when the gain of the current sensor 70 is changed to 0.769, the phase current of the motor 60 may be measured to be 0.769 times that when the current sensor 70 is in a normal state.

For example, the offset fault classification model for the current sensor 70 may be trained through data obtained while changing the offset of the current sensor 70 to +0.2 [A], +0.25 [A], +0.3 [A], −0.2 [A], −0.25 [A], and −0.3 [A]. For example, when the offset of the current sensor 70 is changed to +0.2 [A], the phase current of the motor 60 may be measured to be +0.2 [A] higher than when the current sensor 70 is in a normal state.

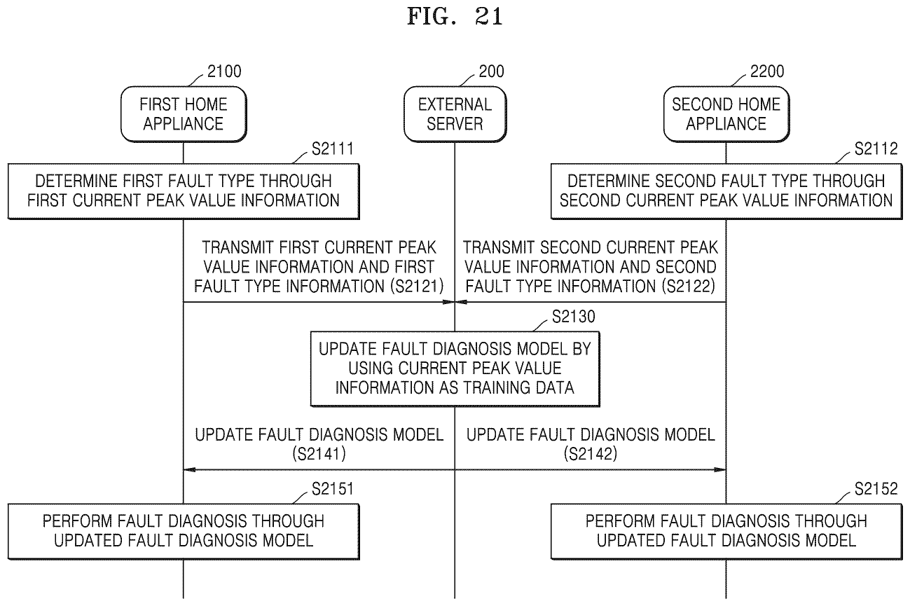

However, the fault types and training data according to the present disclosure are not limited to the above-mentioned embodiment. The fault diagnosis model 120 based on various fault types may be additionally deployed to the microcontroller of the home appliance 100, and the training data may also be updated. This will be described below with reference to FIG. 21.

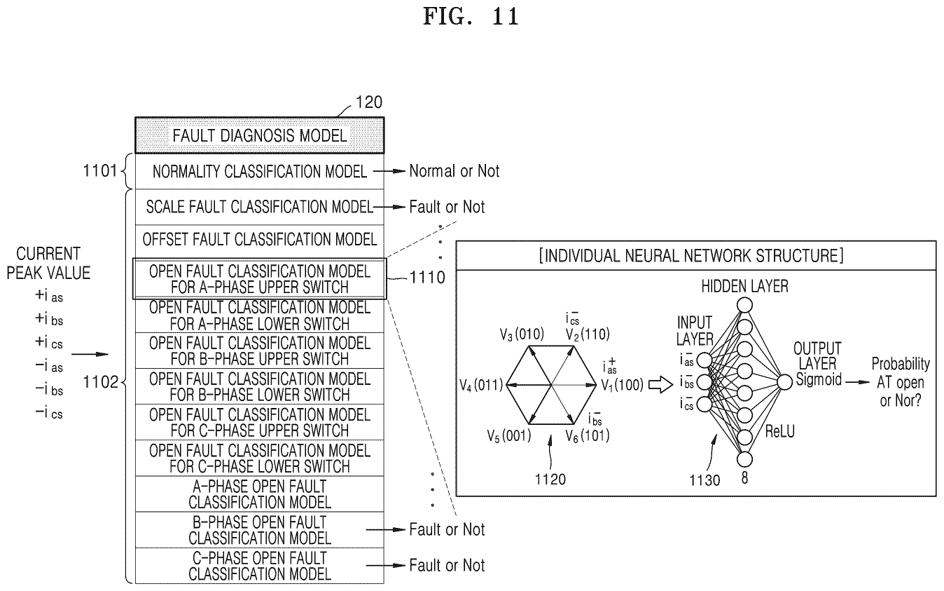

FIG. 11 is a diagram for describing an operation in which a fault diagnosis model individually diagnoses a plurality of fault types, according to an embodiment of the present disclosure.

Referring to FIG. 11, the processor 110 according to an embodiment may apply current peak value information to the fault diagnosis model 120 to diagnose a fault in the home appliance 100. For example, the current peak value information may be a phase current of the motor 60 generated according to six effective voltage vectors. For example, the current peak value information may include three-phase positive currents +ia, +ib, and +ic and three-phase negative currents −ia, −ib, and −ic, as shown in FIG. 6B. Alternatively, for example, the current peak value information may also include dq-axis current information, or DC link current information.

In an embodiment, the processor 110 may output diagnosis result for a plurality of fault types through a binary classification model including individual neural networks for the plurality of fault types, respectively. For example, a normality classification model 1101 may receive current peak value information as input and output whether the inverter 50 is normal or not, through a neural network operation. For example, the plurality of fault type classification models 1102 may receive current peak value information as input and output whether the current peak value information corresponds to the plurality of fault types, respectively.

In an embodiment, the binary classification model including the individual neural networks receives training data and outputs it to an output node through a hidden layer of the neural network model, under control of the processor 110. Each binary classification model may include one hidden layer having a ReLU activation function. The output node may output fault diagnosis results for 12 fault types by fault ID through a softmax activation function. Here, the binary classification model may output a result for normality and results for 11 fault types as fault IDs and probability values according to the fault IDs, and the probability values may be output as results of 0 or 1 for the respective fault IDs through one-hot encoding of the embedded system.

In an embodiment, the binary classification model may receive three or more of six pieces of current peak value information according to the six effective voltage vectors as input, and diagnose a fault in the home appliance 100. For example, in response to receiving only data according to V1(1,0,0), V2(1,1,0), and V6(1,0,1) that control the A-phase upper switch S1 to the on state among the effective voltage vectors, an open fault classification model 1110 for the A-phase upper switch may diagnose whether there is an open fault of the A-phase upper switch S1. For example, in response to receiving only data according to V3(0,1,0), V4(0,1,1), and V5(0,0,1) that control the A-phase lower switch S2 to the on state among the effective voltage vectors, an open fault classification model for the A-phase lower switch may diagnose whether there is an open fault of the A-phase lower switch S2. For example, in response to receiving only data according to V2(1,1,0), V3(0,1,0), and V4(0,1,1) that control the B-phase upper switch S3 to the on state among the effective voltage vectors, an open fault classification model for the B-phase upper switch may diagnose whether there is an open fault of the B-phase upper switch S3. For example, in response to receiving only data according to V1(1,0,0), V6(1,0,1), and V5(0,0,1) that control the B-phase lower switch S4 to the on state among the effective voltage vectors, an open fault classification model for the B-phase lower switch may diagnose whether there is an open fault of the B-phase lower switch S4. For example, in response to receiving only data according to V4(0,1,1), V5(0,0,1), and V6(1,0,1) that control the C-phase upper switch S5 to the on state among the effective voltage vectors, an open fault classification model for the C-phase upper switch may diagnose whether there is an open fault of the C-phase upper switch S5. For example, in response to receiving only data according to V1(1,0,0), V2(1,1,0), and V3(0,1,0) that control the C-phase lower switch S6 to the on state among the effective voltage vectors, an open fault classification model for the C-phase lower switch may diagnose whether there is an open fault of the C-phase lower switch S6.

In an embodiment, the binary classification model may have one output node. In an embodiment, the accuracy of binary classification of the binary classification model may be determined according to the number of nodes in the hidden layer. For example, when the number of nodes in the hidden layer is eight or more, certain accuracy may be achieved. However, the number of nodes in the hidden layer is only an example, and may be 2, 4, 6, 8, 12, or the like.

A process of determining whether there is an open fault of the A-phase upper switch S1 of the inverter 50 by using the open fault classification model 1110 for the A-phase upper switch according to an embodiment will be described.

When only data of +ia according to V1(1,0,0), −ib according to V6(1,0,1), and −ic according to V2(1,1,0) among six effective voltage vectors 1120 is received, the open fault classification model 1110 for the A-phase upper switch may distinguish between an open fault and normality of the A-phase upper switch S1. The processor 110 may apply input data to the open fault classification model 1110 for the A-phase upper switch to output the presence of a fault as a probability value. The probability value may be output as a result of 0 or 1 for each fault ID through one-hot encoding of the embedded system.

In the home appliance 100 according to an embodiment of the present disclosure, because the fault diagnosis model 120 includes a binary classification model, and the binary classification model includes individual neural networks according to a plurality of fault types, the fault diagnosis model 120 may diagnose a fault in the home appliance 100 even in a complex fault situation in which several types of faults occur in combination.

The home appliance 100 according to an embodiment of the present disclosure may deploy the fault diagnosis model 120 to an embedded system, and may diagnose a fault in the home appliance 100 in real time under control of the processor 110 on the microcontroller. Thus, the home appliance 100 may quickly determine the presence of a fault in the home appliance 100 and the fault type.

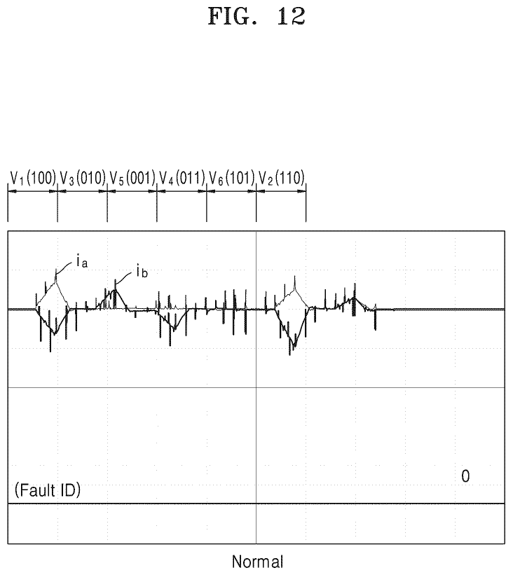

FIGS. 12 to 16 are graphs showing current peak value information for each fault type and predicted fault types, according to an embodiment of the present disclosure.

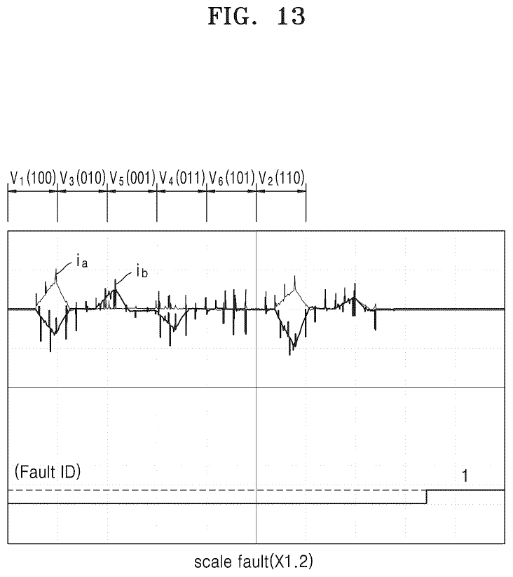

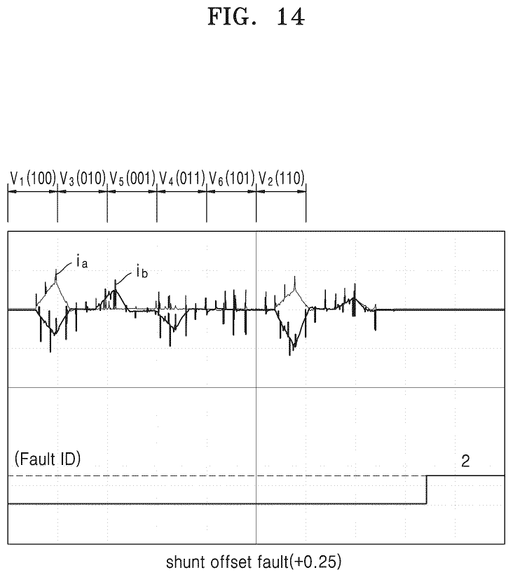

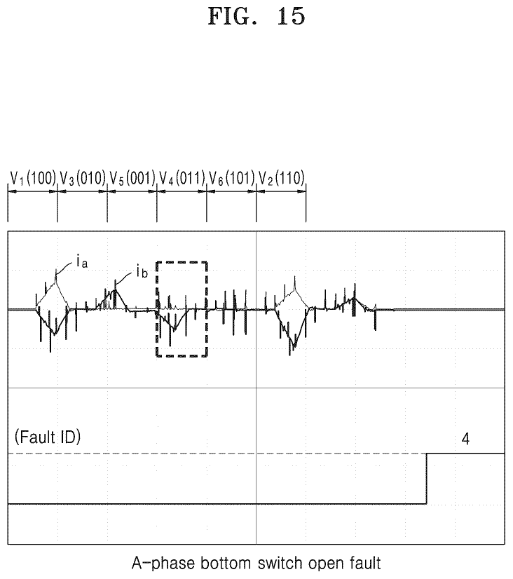

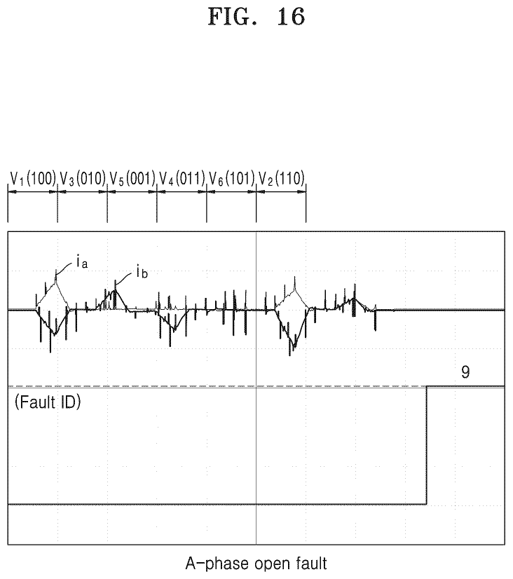

FIG. 12 shows current peak value information in a normal state. FIG. 13 shows current peak value information in a scale fault state of the current sensor 70. FIG. 14 shows current peak value information in an offset fault state of the current sensor 70. FIG. 15 shows current peak value information in an open fault state of the A-phase lower switch S2. FIG. 16 shows current peak value information in an A-phase open state. For convenience of description, FIGS. 12 to 16 show only current peak value information of phase a and current peak value information of phase b, which are two phases among the three-phase currents.

In the examples of FIGS. 12 to 16, the application order of the effective voltage vectors is V1(1,0,0), V3(0,1,0), V5(0,0,1), V4(0,1,1), V6(1,0,1), and V2(1,1,0), which is the same as in FIG. 7.

In FIG. 12, when the inverter 50 is in a normal state, the processor 110 may obtain current peak value information in the order of +ia, +ib, +ic, −ia, −ib, and −ic according to the application order of the effective voltage vectors. The processor 110 may apply the current peak value information to the normality classification model to obtain a fault ID for normality (fault ID: 0). For example, the processor 110 may obtain a diagnosis result indicating that the inverter 50 is normal.

In FIG. 13, in a scale fault state of the current sensor 70, the current peak value information may be measured to be 1.2 times that when the current sensor 70 is in a normal state. The processor 110 may apply the measured current peak value information to the scale fault classification model to obtain a fault ID for the presence of a scale fault (fault ID: 1). For example, the processor 110 may obtain a diagnosis result indicating a scale fault of the current sensor 70.

In FIG. 14, in an offset fault state of the current sensor 70, the current peak value information may be measured to be +0.25 [A] higher than when the current sensor 70 is in a normal state. The processor 110 may apply the measured current peak value information to the offset fault classification model to obtain a fault ID for the presence of an offset fault (fault ID: 2). For example, the processor 110 may obtain a diagnosis result indicating an offset fault of the current sensor 70.

In FIG. 15, in an open fault state of the A-phase lower switch S2 of the inverter 50, even according to the application order of the effective voltage vectors, the processor 110 may not obtain current peak value information in the order of +ia, +ib, +ic, −ia, −ib, and −ic. In detail, in an open fault state of the A-phase lower switch S2, even when the processor 110 applies the effective voltage vector of V4 (0,1,1) to the inverter 50, the processor 110 may not obtain the current peak value information of −ia. The processor 110 may apply the measured current peak value information to the open fault classification model of the A-phase lower switch to obtain a fault ID for the presence of an open fault of the A-phase lower switch (fault ID: 4). For example, the processor 110 may obtain a diagnosis result indicating an open fault of the A-phase lower switch S2 of the inverter 50.

In FIG. 16, in an A-phase open fault state of the inverter 50, even according to the application order of the effective voltage vectors, the processor 110 may not obtain current peak value information in the order of +ia, +ib, +ic, −ia, −ib, and −ic. In detail, in the A-phase open fault state, the processor 110 may not obtain the current peak value information of +ia. The processor 110 may apply the measured current peak value information to the A-phase open fault classification model to obtain a fault ID for the presence of an A-phase open fault (fault ID: 9). For example, the processor 110 may obtain a diagnosis result indicating an A-phase open fault of the inverter 50.

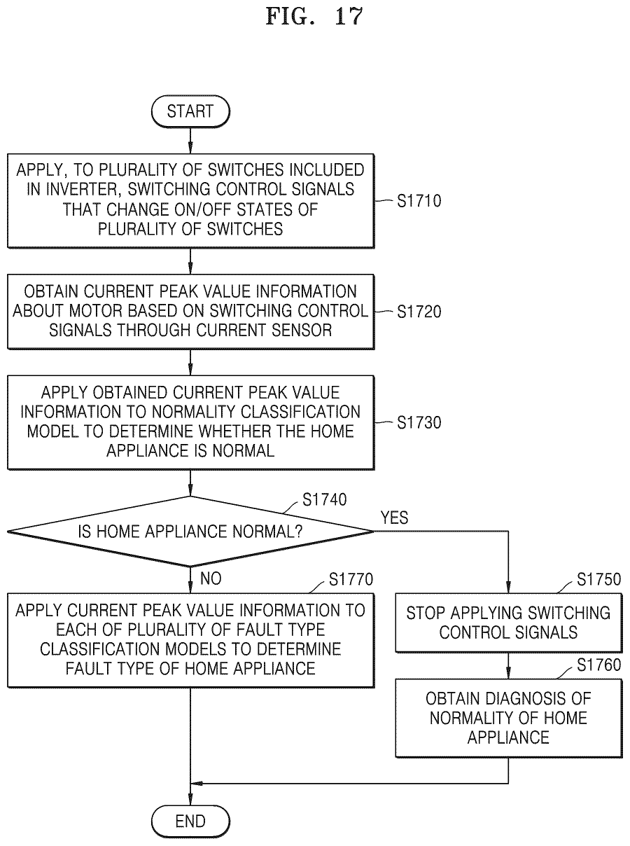

FIG. 17 is a flowchart of a method of diagnosing a fault in a home appliance, according to an embodiment of the present disclosure.

Referring to FIG. 17, the home appliance 100 according to an embodiment of the present disclosure may first apply the normality classification model 1101 (see FIG. 11) to determine whether the home appliance 100 is normal, and based on identifying that the home appliance 100 is abnormal, execute 11 fault type classification models 1102 (see FIG. 11) to determine the fault type. In response to identifying that the home appliance 100 is normal, the home appliance 100 may stop control of the inverter 50 and diagnose that the home appliance 100 is normal.

In operation S1710, the home appliance 100 may apply, to the plurality of switches included in the inverter 50, switching control signals that change on/off states of the plurality of switches. Operation S1710 may correspond to operation S310 of FIG. 3.

In operation S1720, the home appliance 100 may sense current peak value information about the motor 60 based on the switching control signals through the current sensor 70. Operation S1720 may correspond to operation S320 of FIG. 3.

In operation S1730, the home appliance 100 may apply the obtained current peak value information to the normality classification model 1101 to determine whether the home appliance is normal.

In operation S1740, the home appliance 100 may identify whether the home appliance 100 is normal, based on an output value of the normality classification model 1101. In response to identifying, in operation S1740, that the home appliance 100 is normal, the home appliance 100 may operate according to operation S1750 or operation S1760. In response to identifying, in operation S1740, that the home appliance 100 is abnormal, the home appliance 100 may operate according to operation S1770.

In operation S1750, in response to identifying that the home appliance 100 is normal, the home appliance 100 may stop control of the inverter 50. For example, the home appliance 100 may stop applying the switching control signals. In operation S1760, the home appliance 100 determines that the home appliance 100 is normal, and terminate the fault diagnosis operation of the home appliance 100.

In operation S1770, in response to identifying that the home appliance 100 is abnormal, the home appliance 100 may apply the current peak value information to each of the plurality of fault type classification models 1102 to determine the fault type of the home appliance 100. For example, the home appliance 100 may individually determine a plurality of fault types through a binary classification model including individual neural network models respectively for 11 fault types.

FIG. 18 is a block diagram illustrating a configuration of a home appliance according to an embodiment of the present disclosure.

Referring to FIG. 18, the home appliance 100 may include the inverter 50, the motor 60, the current sensor 70, the processor 110, memory 121 including the fault diagnosis model 120, the communication module 130, and the user interface 140. The home appliance 100 may be configured in various combinations of the components illustrated in FIG. 18, and not all the components illustrated in FIG. 18 are essential components.

The memory 121 stores various pieces of information, data, instructions, programs, and the like necessary for the operation of the home appliance 100. The instructions, when executed by at least one processor, may cause the home appliance to perform various operations. The memory 121 may include at least one of a volatile memory or a non-volatile memory, or a combination thereof. The memory 121 may include at least one of a flash memory-type storage medium, a hard disk-type storage medium, a multimedia card micro-type storage medium, a card-type memory (e.g., Secure Digital (SD) or extreme Digital (XD) memory), random-access memory (RAM), static RAM (SRAM), read-only memory (ROM), electrically erasable programmable ROM (EEPROM), programmable ROM (PROM), magnetic memory, a magnetic disk, and an optical disc. In addition, the home appliance 100 may operate a web storage or a cloud server that performs a storage function on the Internet.

The communication module 130 may include at least one of a short-range communication module or a long-range communication module, or a combination thereof. The communication module 130 may include at least one antenna for wireless communication with other devices. The short-range communication module may include, but is not limited to, a Bluetooth communication module, a Bluetooth Low Energy (BLE) communication module, an NFC module, a wireless local area network (WLAN) (Wi-Fi) communication module, a Zigbee communication module, an IrDA communication module, a Wi-Fi Direct (WFD) communication module, an ultra-wideband (UWB) communication module, an Ant+ communication module, a microwave (uWave) communication module, and the like.

The user interface 140 may include an input interface and an output interface. The input interface may include a key, a touch screen, and the like. The input interface receives a user input and delivers it to the processor 110. The output interface may include a display, a speaker, and the like. The output interface outputs various notifications, messages, information, and the like generated by the processor 110. For example, the processor 110 may receive a diagnostic command from a user through the input interface. For example, the processor 110 may output a fault diagnosis result of the home appliance 100 through the display. For example, the processor 110 may output a fault diagnosis result of the home appliance 100 through the speaker.

The processor 110 controls the overall operation of the home appliance 100. The processor 110 may execute a program stored in the memory 121 to control the components of the home appliance 100. According to an embodiment of the present disclosure, the processor 110 may include a separate NPU configured to perform an operation of an artificial intelligence model. In addition, the processor 110 may include a CPU, a GPU, and the like.

The external server 200 may include a communication module for performing communication with an external device. The home appliance 100 may connect to a network through an access point (AP) device to access the external server 200. The external server 200 may include an artificial intelligence (AI) processor. The Al processor may train an artificial neural network to generate an artificial intelligence model for fault diagnosis of the home appliance 100. The external server 200 may train the fault diagnosis model 120 and deploy it to the home appliance 100.

The processor 110 according to an embodiment of the present disclosure may receive a diagnostic command for the home appliance 100 from an external server. The processor 110 may transmit a fault diagnosis result of the home appliance 100 to the external server 200 through the communication module 130.

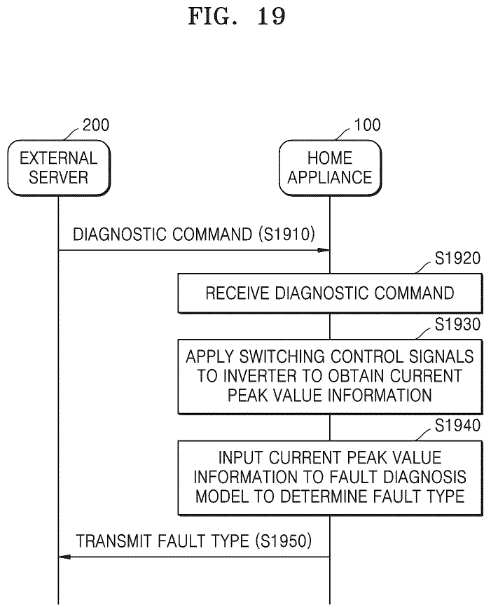

FIG. 19 is a flowchart of a method, performed by a home appliance and an external server, of diagnosing a fault, according to an embodiment of the present disclosure.

Referring to FIG. 19, the home appliance 100 may connect to a network through an AP device to access the external server 200.

In operation S1910, the external server 200 may transmit a diagnostic command to the home appliance 100. For example, the external server 200 may transmit and receive information to and from the home appliance 100 through a particular application installed in the home appliance 100.

In operation S1920, the home appliance 100 may receive the diagnostic command from the external server 200 through the communication module 130. In response to receiving the diagnostic command, the home appliance 100 may perform a fault diagnosis operation of the home appliance 100.

In operation S1930, the home appliance 100 may apply switching control signals to the inverter 50 to obtain current peak value information. In operation S1940, the home appliance 100 may input the current peak value information to the fault diagnosis model 120 to determine the fault type.

The home appliance 100 according to an embodiment of the present disclosure may deploy the fault diagnosis model 120 to an embedded system, and may diagnose a fault in the home appliance 100 in real time under control of the processor 110 on the microcontroller. Thus, the home appliance 100 may quickly determine the presence of a fault in the home appliance 100 and the fault type.

In operation S1950, the home appliance 100 may transmit the fault type to the external server 200 through the communication module 130.

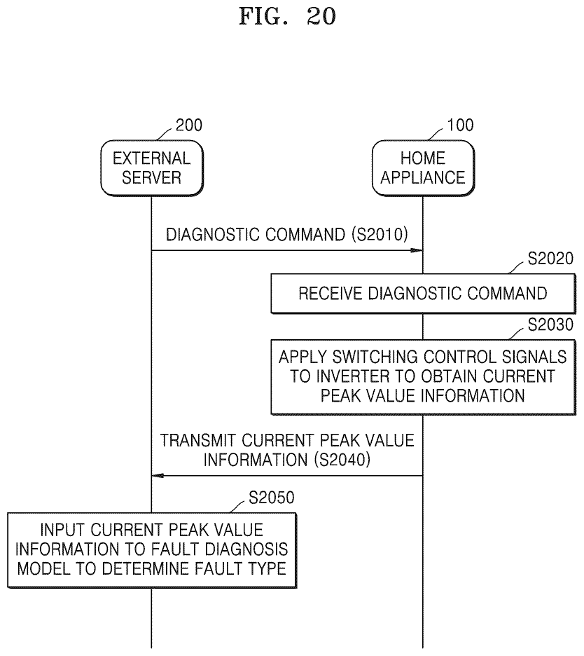

FIG. 20 is a flowchart of a method, performed by a home appliance and an external server, of diagnosing a fault, according to an embodiment of the present disclosure.

In operation S2010, the external server 200 may transmit a diagnostic command to the home appliance 100.

In operation S2020, the home appliance 100 may receive the diagnostic command from the external server 200 through the communication module 130. In response to receiving the diagnostic command, the home appliance 100 may perform a fault diagnosis operation of the home appliance 100.

In operation S2030, the home appliance 100 may apply switching control signals to the inverter 50 to obtain current peak value information.

In operation S2040, the home appliance 100 may transmit the Current peak value information to the external server 200 through the communication module 130.

In operation S2050, the External server 200 may input the current peak value information to the fault diagnosis model 120 to determine the fault type.

Because the home appliance 100 according to an embodiment of the present disclosure diagnoses the fault type through the external server 200, the amount of computation of the processor 110 may be reduced.

FIG. 21 is a flowchart illustrating a method, performed by an external server and home appliances, of updating a fault diagnosis model, according to an embodiment of the present disclosure.

Referring to FIG. 21, the external server 200 may update the fault diagnosis model 120 by using, as training data, current data received from a plurality of home appliances.

In operation S2111, a first home appliance 2100 may determine a first fault type through first current peak value information. For example, the first home appliance 2100 may apply switching control signals to the inverter 50 through the method described above with reference to FIG. 3 to obtain the first current peak value information. The first home appliance 2100 may apply the first current peak value information to the fault diagnosis model 120 to determine a first fault type.

In operation S2121, the first home appliance 2100 may transmit the first current peak value information and first fault type information to the external server 200. The first home appliance 2100 may also transmit the first current peak value information or the first fault type information to the external server 200.

In operation S2112, a second home appliance 2200 may determine a second fault type through second current peak value information. In operation S2122, the second home appliance 2200 may transmit the second current peak value information and second fault type information to the external server 200. The second home appliance 2200 may also transmit the second current peak value information or the second fault type information to the external server 200.

In operation S2130, the external server 200 may update the fault diagnosis model 120 by using the current peak value information as training data. For example, the external server 200 may use the first current peak value information as training data for a first binary classification model according to the first fault type information. The external server 200 may update the first binary classification model. For example, the external server 200 may use the second current peak value information as training data for a second binary classification model according to the second fault type information. The external server 200 may update the second binary classification model.

In operations S2141 and S2142, the external server 200 may deploy the updated fault diagnosis model to the first home appliance 2100 and the second home appliance 2200.

In operations S2151 and S2152, the first home appliance 2100 and the second home appliance 2200 may each perform fault diagnosis through the updated fault diagnosis model.

In addition, the external server 200 may generate a fault diagnosis model that is trained to infer additional fault types. The external server 200 may also deploy, to the home appliance 100, a fault diagnosis model that determines the presence of a fault according to an additional fault type.

A method of diagnosing a fault in a home appliance 100 according to an embodiment of the present disclosure may include applying, a plurality of switches included in an inverter 50 of the home appliance 100, switching control signals that change on/off states of the plurality of switches, obtaining, through a current sensor 70, current peak value information about a motor 60 based on the switching control signals, and determining a fault in the home appliance 100 by applying the obtained current peak value information to a fault diagnosis model 120 that is pre-trained to infer a fault in the home appliance 100.

The determining of the fault in the home appliance 100 may include determining a fault type of the home appliance 100. The fault type of the home appliance 100 may include at least one of an open fault of at least one of a plurality of switches included in the inverter 50, an open fault of at least one of a plurality of phases of the inverter 50, a scale fault of the current sensor 70, or an offset fault of the current sensor 70.

The applying of the switching control signals to the plurality of switches may include sequentially applying the switching control signals to the plurality of switches according to a predefined order.

The method of diagnosing a fault in the home appliance 100 may further include generating the switching control signals in a PWM manner according to a plurality of effective voltage vectors.

The generating of the switching control signals may include generating the switching control signals based on an application order, magnitudes, or application times of the plurality of effective voltage vectors.

The fault diagnosis model 120 may include a binary classification model having a neural network for determining a fault type.

The fault diagnosis model may include a plurality of binary classification models that are pre-trained to infer a plurality of fault types, respectively. The method of diagnosing a fault in the home appliance 100 may further include obtaining diagnosis results for the plurality of fault types through the plurality of binary classification models, respectively.

The fault diagnosis model 120 may include a normality classification model that is pre-trained to infer whether the home appliance 100 is normal, and a plurality of fault type classification models that are pre-trained to infer a plurality of fault types, respectively. The determining of the fault in the home appliance 100 may include determining whether the home appliance 100 is normal by applying the obtained current peak value information to the normality classification model, stopping, based on determining that the home appliance 100 is normal, applying the switching control signals, and determining, based on determining that the home appliance 100 is abnormal, the fault type of the home appliance 100 by applying the obtained current peak value information to each of the plurality of fault type classification models.

The method of diagnosing a fault in the home appliance 100 may further include determining whether there is a short-circuit fault of the inverter 50, stopping, based on determining that there is a short-circuit fault of the inverter 50, applying the switching control signals, and obtaining, based on determining that there is no short-circuit fault of the inverter 50, current peak value information based on the switching control signals.

The method of diagnosing a fault in the home appliance 100 may further include generating training data regarding a presence of a fault based on the obtained current peak value information, and updating the fault diagnosis model 120 based on the training data.

The method of diagnosing a fault in the home appliance 100 may include receiving a diagnostic command for the home appliance 100 from an external server 200, and transmitting a fault diagnosis result of the home appliance 100 to the external server 200 through a communication module 130 of the home appliance 100.

A machine-readable storage medium may be provided in the form of a non-transitory storage medium. Here, the term ‘non-transitory storage medium’ refers to a tangible device and does not include a signal (e.g., an electromagnetic wave), and the term ‘non-transitory storage medium’ does not distinguish between a case where data is stored in a storage medium semi-permanently and a case where data is stored temporarily. For example, the ‘non-transitory storage medium’ may include a buffer in which data is temporarily stored.

According to an embodiment, methods according to various embodiments disclosed herein may be included in a computer program product and then provided. The computer program product may be traded as commodities between sellers and buyers. The computer program product may be distributed in the form of a machine-readable storage medium (e.g., a compact disc ROM (CD-ROM)), or may be distributed online (e.g., downloaded or uploaded) through an application store or directly between two user devices (e.g., smart phones). In a case of online distribution, at least a portion of the computer program product (e.g., a downloadable app) may be temporarily stored in a machine-readable storage medium such as a manufacturer's server, an application store's server, or a memory of a relay server.

What is claimed is:

1. A method of diagnosing a fault in a home appliance comprising an inverter configured to convert direct current power into alternating current power to drive a motor, and a current sensor configured to measure current peak value information about the motor, the method comprising:
applying, to a plurality of switches included in the inverter, switching control signals that change on and off states of the plurality of switches;
obtaining, through the current sensor, current peak value information about the motor based on the switching control signals; and
identifying the fault in the home appliance by applying the obtained current peak value information to a fault diagnosis model that is pre-trained to infer the fault in the home appliance.

2. The method of claim 1, wherein the identifying the fault in the home appliance comprises identifying a fault type of the home appliance, and
wherein the fault type of the home appliance comprises at least one of an open fault of at least one of the plurality of switches included in the inverter, an open fault of at least one of a plurality of phases of the inverter, a scale fault of the current sensor, or an offset fault of the current sensor.

3. The method of claim 1, wherein the applying the switching control signals to the plurality of switches comprises sequentially applying the switching control signals to the plurality of switches according to a predefined order.

4. The method of claim 1, further comprising generating the switching control signals in a pulse-width modulation (PWM) manner according to a plurality of effective voltage vectors.

5. The method of claim 4, wherein the generating the switching control signals comprises generating the switching control signals based on an application order, magnitudes, or application times of the plurality of effective voltage vectors.

6. The method of claim 1, wherein the fault diagnosis model comprises a binary classification model having a neural network for identifying a fault type.

7. The method of claim 1, wherein the fault diagnosis model comprises a plurality of binary classification models that are pre-trained to infer a plurality of fault types, respectively, and
wherein the method further comprises obtaining diagnosis results for the plurality of fault types through the plurality of binary classification models, respectively.

8. The method of claim 1, wherein the fault diagnosis model comprises a normality classification model that is pre-trained to infer whether the home appliance is normal, and a plurality of fault type classification models that are pre-trained to infer a plurality of fault types, respectively, and
wherein the identifying the fault in the home appliance comprises:
identifying whether the home appliance is normal by applying the obtained current peak value information to the normality classification model;
based on identifying that the home appliance is normal, stopping applying the switching control signals; and
based on identifying that the home appliance is abnormal, identifying a fault type of the home appliance by applying the obtained current peak value information to each of the plurality of fault type classification models.

9. The method of claim 1, further comprising:
identifying whether there is a short-circuit fault of the inverter;
based on identifying that there is the short-circuit fault of the inverter, stopping applying the switching control signals; and
based on identifying that there is no short-circuit fault of the inverter, obtaining current peak value information based on the switching control signals.

10. The method of claim 1, further comprising:
generating training data regarding a presence of the fault based on the obtained current peak value information; and
updating the fault diagnosis model based on the training data.

11. The method of claim 1, further comprising:
obtaining a diagnostic command for the home appliance from an external server; and
transmitting a fault diagnosis result of the home appliance to the external server through a communication interface of the home appliance.

12. A home appliance comprising:
a motor;
an inverter configured to generate alternating current power from direct current power, to drive the motor;
a current sensor configured to measure current peak value information about the motor;
memory storing instructions, and a fault diagnosis model that is pre-trained to infer a fault in the home appliance; and
at least one processor,
wherein the instructions, when executed by the at least one processor, cause the home appliance to:
apply, to a plurality of switches included in the inverter, switching control signals that change on and off states of the plurality of switches;
obtain, through the current sensor, current peak value information about the motor based on the switching control signals; and
identify the fault in the home appliance by applying the obtained current peak value information to the fault diagnosis model.

13. The home appliance of claim 12, wherein the instructions, when executed by the at least one processor, cause the home appliance to identify a fault type of the home appliance, and
wherein the fault type of the home appliance comprises at least one of an open fault of at least one of the plurality of switches included in the inverter, an open fault of at least one of a plurality of phases of the inverter, a scale fault of the current sensor, or an offset fault of the current sensor.

14. The home appliance of claim 12, wherein the fault diagnosis model comprises a plurality of binary classification models that are pre-trained to infer a plurality of fault types, respectively, and
wherein the instructions, when executed by the at least one processor, cause the home appliance to obtain diagnosis results for the plurality of fault types through the plurality of binary classification models, respectively.

15. The home appliance of claim 12, wherein the fault diagnosis model comprises a normality classification model that is pre-trained to infer whether the home appliance is normal, and a plurality of fault type classification models that are pre-trained to infer a plurality of fault types, respectively, and
wherein the instructions, when executed by the at least one processor, cause the home appliance to:
identify whether the home appliance is normal by applying the obtained current peak value information to the normality classification model;
stop, based on identifying that the home appliance is normal, applying the switching control signals; and
identify, based on identifying that the home appliance is abnormal, a fault type of the home appliance by applying the obtained current peak value information to each of the plurality of fault type classification models.
